(19) United States
(12) Patent Application Publication
(10) Pub. No.: US 2024/0255574 A1
(43) Pub. Date: Aug. 1, 2024

(54) REAL TIME SIZING TOOL USING GENERIC MODELING OF ENERGY STORAGE SYSTEM

(71) Applicant: Ariel Scientific Innovations Ltd., Ariel (IL)

(72) Inventors: Ilan AHARON, Ariel (IL); Aaron SHMARYAHU, Ariel (IL)

(73) Assignee: Ariel Scientific Innovations Ltd., Ariel (IL)

(21) Appl. No.: 18/562,357

(22) PCT Filed: May 19, 2022
(86) PCT No.: PCT/IL2022/050524

§ 371 Date: Nov. 20, 2023

Related U.S. Application Data
(60) Provisional application No. 63/190,952, filed on May 20, 2021.

(51) Int. Cl. G01R 31/367; G01R 31/374; G01R 31/385; G01R 31/396

(52) U.S. Cl. CPC G01R 31/367; G01R 31/374; G01R 31/386; G01R 31/396

(57) ABSTRACT

A method of modeling a battery to match the battery to a task, the method comprises: selecting a battery, testing the battery for charge rate and discharge rate at different temperatures, collecting results; and interpolating in between and extrapolating around the collected results to produce a model of behavior of the battery and predict operating points, so that the battery may be sized and matched to given tasks.

### RELATED APPLICATION/S

This application claims the benefit of priority of U.S. Provisional Patent Application No. 63/190,952 filed on 20 May 2021, the contents of which are incorporated herein by reference in their entirety.

### FIELD AND BACKGROUND OF THE INVENTION

The present invention, in some embodiments thereof, relates generic modeling of an energy storage system such as a battery and to a real time sizing method and tool for such an energy storage system that uses generic modeling.

Global warming and climate change are widely recognized phenomena nowadays. Minimizing the greenhouse effect, is a key component of suppressing global warming by diminishing emission and air pollution. The greenhouse effect is caused by a variety of factors, one being the transportation industry, particularly the internal-combustion engine.

The transportation sector includes two main industries: the airline industry and the automotive industry. The heavy vehicle sector consists mainly of diesel-powered vehicles where diesel-based fuels are made from environmentally harmful material. Therefore, diesel engines emit pollutants, which increase the greenhouse effect and global warming. Over the years, the automotive industry has evolved substantially, resulting in a considerable increase in fuel consumption. The uses of an electric-powered propulsion system such as in the electric-vehicle (EV) and hybrid-electric vehicle (HEV) are suitable solutions to arrive at the zero emission vehicle. EV and HEV constitute a storage unit for supplying reliable energy into electrically operated motors. Battery operated motors are now widely used in land vehicle applications, manned and unmanned aerial vehicles and naval vehicles, but still provide fertile ground for research.

Electrically-powered propulsion systems are thus relatively common today both for nonmilitary and military vehicles. In civilian applications, systems with battery-operated vehicle propulsion produce zero emissions in use. Furthermore, military vehicles with electrically operated propulsions systems ensure reduced or zero thermal and acoustic signatures. These features encourage the use of the electric motor over traditional internal-combustion engines.

The penetration of renewable-energy sources has increased dramatically over the past decades. However, wind-turbine and photovoltaic cells are stochastic sources and cannot be use as a trustworthy energy source. Nevertheless, by adding an intermediate battery storage unit to statistical sources, an energy system may become robust and reliable.

Another renewable and sustainable source is a fuel-cell (FC). Some of them are fed by methanol, others by hydrogen, and the theoretical upper efficiency is 95%. Nevertheless, although FCs contain a high energy density, the power density is poor and therefore the size of the source is set by the peak power or by adding a power battery-storage unit. In such a case, the minimum size of the FC is the load average power. Different energy sources may be categorized by energy and power density. A Ragon Diagram as shown in FIG. 1, displays various kinds of energy sources in terms of power density and energy density.

A Ragon Diagram classifies the sources according to their locations in the diagram. The more the source is to the right, the more energetic it is. Likewise, the higher up the sources is in the diagram, the greater its ability to supply power. For example, an internal-combustion engine (gasoline and diesel-based) is very energetic but has a lower power. While added to the basic weight of an internal-combustion engine, the weight of the fuel is relatively low for this engine's base weight. The weight of the fuel marginally affects the engine, and the fuel allows for an increase in the engine's range of travel. On the other hand, the super-capacitor located at the top of the diagram, may provide the most power density. Nonetheless, the energy density of the super-capacitor is one of the poorest of all the sources.

There are many types of batteries, such as Lead-Acid, Ni—Cd, Ni-MH, Li-ion, and Li-Polymer. Li-ion batteries have the best energy density parameters and can be used for a variety of applications, varying from a storage source for an electric vehicle to a storage source for a power-supply system. Li-Ion commercial rechargeable batteries may reach energy densities of 250-300 [Wh/kg]. Sion Power company has developed a Li-Ion battery having an energy density of 400-600 [Wh/kg] and a power density of about 500 [W/kg] [23].

In general, there are two types of batteries: Power Batteries and Energy Batteries. The first type, Power Batteries, can provide dynamic power but supply energy for a short amount of time, meaning that these batteries can deliver a much higher current than their rated current. On the other hand, the second type, Energy Batteries, provide an average level of power over a long period of time. Unlike Power Batteries, Energy Batteries cannot provide dynamic power; that is, their high current cannot surpass the rated current. In order to design the battery model so that the results are as accurate as possible, the real behavior of the sources needs to be considered. As an example of a way to predict real behavior of sources, a battery may be tested in various real-time situations.

The process of designing and operating a hybrid energy source for a specific application involves two typically serially executed stages. The first one is usually referred to as “sizing”. In the sizing stage, a composition of a hybrid energy source is determined, i.e. which sources should be connected, what the rating of each is and what the interconnection topology is, whether direct or via a power-electronics interface. The ultimate sizing goal is to ensure that the load power request is instantaneously satisfied by the source. A secondary goal is, of course, minimizing cost/weight/volume. Sizing is usually accomplished according to a nominal load profile, say power versus time or vehicle speed versus time in case of transportation applications, the latter also known as the “driving cycle”, and the profiles may be based on manufacturer provided nominal power and energy densities of electrical sources. However, a load profile frequently contains elements of randomness and may best be represented by a histogram rather than analytically. Moreover, as shown by the present authors, these numbers are misleading and can seldom be reached in reality. Additionally, power and energy densities of mentioned electrical sources vary in time (ageing), and are highly dependent on temperature, state of charge and discharge rate. The second stage is real-time operation where an energy management algorithm is executed, determining the amount of power each of the sources may supply/absorb at any instant to satisfy load power demand. Nevertheless, once a hybrid source is composed, different energy management strategies may yield different performances. The hybrid source is designed during a sizing process, but generally without any particular energy management strategy being considered. Hence the sizing process does in fact need to be carried out while taking a specific energy management strategy into account. The strategy considered should furthermore be that expected to be used during real-time operation. Furthermore, the energy management strategy should typically be fuel minimization oriented according to the available power source. Thus, both stages may be combined into a single stochastic design problem.

Batteries are the most common device utilized for electrical energy storage. Battery packs based on basic cells such as Li-ion are used in many applications; for instance, laptops, electronic moveable devices, smart phones, and portable energy storage. Energy management may be implemented for various purposes such as voltage stability, peak shaving, and renewable-energy time shifting. In these applications, it is important to measure the state of charge (SoC) of the cells, which is defined as the available capacity (in Ah) at any point during a charge/discharge cycle, represented as a percentage of battery rated capacity. The SoC parameter may be viewed as a thermodynamic quantity enabling one to assess the potential energy of a battery. It is also important to estimate the state of health (SoH) of a battery, which represents a measure of the battery's ability to store and deliver electrical energy, compared with a new battery. Estimation methods of SoC and SoH are mainly used in three approaches: a coulomb counting method [33], voltage method [34], and Kalman filter method [35]. The coulomb counting method, also known as ampere hour counting and current integration, is the most common technique for calculating the SoC. This method employs battery current readings mathematically integrated over the usage period to calculate SOC values given by

$$SoC = SoC ( {t}_{0} ) + \frac{1}{{C}_{rated}} {\int }_{{t}_{0}}^{{t}_{0} + τ} ( {I}_{B} ( t ) - {I}_{loss} ( t ) ) dt \qquad ( 1 )$$

where SoC(t₀) is the initial SoC, I_{B}(t) is the battery current, and Iₜₒₛₛ(t) is the current consumed by the pack loss reaction. Accordingly, the SoC in % is defined as the percentage of the available capacity relative to the battery rated capacity (C_{rated}), given by the manufacturer.

$$SoC = \frac{{C}_{releasable}}{{C}_{rated}} 100 \% \qquad ( 2 )$$

A fully charged battery has a maximal releasable capacity (Cₘₐₓ), which can be different from the rated capacity. In general, Cₘₐₓ is, to some extent, different from C-rated for a newly used battery and will decline with the number of times used or recharged. Cₘₐₓ may be used for evaluating the SoH of a battery.

$$SoH = \frac{{C}_{m a x}}{{C}_{rated}} 100 \% \qquad ( 3 )$$

When a battery discharges, the depth of discharge (DoD) can be expressed as the percentage of the capacity that has been discharged relative to C_{rated}.

$$D o D = \frac{{C}_{R E L E A S E D}}{{C}_{r a t e d}} 100 \% \qquad ( 4 )$$

The Coulomb counting method then calculates the remaining capacity simply by accumulating the charge transferred in or out of the battery. The voltage method converts a reading of the battery voltage to the equivalent SoC value using the known discharge curve on voltage versus SoC of the battery. The Kalman filter is an algorithm to estimate the inner states of any dynamic system—it can also be used to estimate the SoC of a battery. By modeling the battery system to include the wanted unknown quantities (such as SoC) in its state description, the Kalman filter estimates their values and gives error bounds on the estimates. It then becomes a model-based state estimation technique that employs an error correction mechanism to provide real-time predictions of the SoC. The method may be extended to increase the capability of real-time SoH estimation using the extended Kalman filter.

There are many battery modeling options as, over the years, researchers have developed several approaches for battery modeling. Each method brings in different levels of accuracy and complexity with pro and cons. These models can be generally divided into three groups: the electrochemical model, the equivalent electric circuit models, and mathematical models (analytical or stochastic) according to the levels of physical interpretation of battery electrochemical processes presented in the models. The electrochemical method is based on theoretical and practical physical equations of the battery internal electrochemical process. The complete model is described by several partial differential equations with specified boundary conditions. The electrochemical models are usually very accurate and represent the internal electrochemical process. Nevertheless, since the inner processes of the battery are chemical it becomes impractical for electronics engineer to understand and modify the mathematical questions based on the empirical results. Due to the nature of battery technology, many parameters are difficult to acquire. Moreover, since the model consists of partial differential equations and large amounts of data, the electro-chemical model's main disadvantage is the complexity of its computations, and the considerable time needed for these computations.

One option to overcome the challenges of the electrochemical method is by the reduced-order model. The reduced order approach uses additional assumptions neglecting some of the chemical process and ending in a battery average model and reduces the required computing power. However, the considerable loss of information may be sufficient for specific applications as state of charge (SoC) estimation or terminal voltage prediction but insufficient for an accurate battery model with respect to the standard electrochemical model. The equivalent electric circuit model use combinations of current and voltage sources, dependent sources, discrete electrical devices (resistors, capacitors and inductors) and non-linear elements. The electrical equivalent circuit is based on the electrochemical process where the element's value is determined by fitting the experiment's results to circuit parameters. The electric model has several options and is the model that most accurately covers and reflects battery behavior. The simple electrical model includes a voltage source and a Thevenin circuit which contains column resistance to the voltage source. One method is an impedance-based equivalent electronic circuit. The battery complex impedance is calculated by FFT analyzer with an AC sweep (mHz-kHz) source.

Another equivalent electrical circuit was developed by Randle, where the model contains resistor, inductor and capacitor, non-linear resistor and impedance. The I-V based equivalent electrical circuit is based on measurements of terminal voltage, load current and temperature. To avoid complicated analysis with non-linear elements the Randle equivalent electrical circuit is based on an n-order of series RC networks. However, since a battery is a non-linear device, a single RC chain is incapable of predicting the battery behavior over a large range of SoC, battery current and temperature conditions.

Last but not least is the empirical model, based on mathematical equations that describe all specific battery features. Methods such as the support vector machine, wavelet neural network and artificial neural networks describe the battery behavior by intelligent simulating methods without any knowledge of the electromechanical process in the modeled battery. These models offer good tradeoffs between accuracy and executing time due to the model complexity. The performance of these models is largely depending on supplied data on the different operating modes. To achieve a sufficient accuracy with the empirical model, detailed data over a wide-range of operating conditions is required.

### SUMMARY OF THE INVENTION

An empirical model is constructed for a specific battery or type of battery, wherein the battery is selected and then tested under different conditions. Interpolation and extrapolation techniques may be used to obtain results around the specific points tested to provide predicted operating points for the battery. The behavior of the battery in terms of operating points may then be used to match the battery to specific tasks.

According to an aspect of some embodiments of the present invention there is provided a method of modeling a battery to match the battery to a task, the method comprising:
selecting a battery;
testing the battery for charge rate and discharge rate at different temperatures;
collecting results; and
interpolating in between and extrapolating around said collected results to produce a model of behavior of said battery.

The method may comprise repeating said discharge rate tests for different types of discharge.

In embodiments, said discharge types comprise a constant current discharge at a given discharge rate, or a constant voltage discharge, or discharge with a fixed Ohmic load, or a constant power discharge.

The method may comprise repeating said testing the battery for charge rate, for different charging processes.

In embodiments, said charging processes comprise a constant current charging period followed by a constant voltage charging period.

In embodiment, said collecting results comprises tabulating said results in a database.

In embodiments, said database is a three-dimensional database of power, temperature and current.

In embodiments, said interpolation and extrapolation comprises using a linear point slope algorithm.

In embodiments, said interpolation and extrapolation comprises finding a polygonal approximation formed by secants crossing and re-crossing in a given curve.

In embodiments, said interpolation and approximation provides a prediction of a battery operating point between points in said database or outside of but in proximity to said points in said database.

According to a second aspect of the present invention there is provided a method of sizing a battery to match the battery to a task, the method comprising:
selecting a battery;
testing the battery for charge rate and discharge rate at different temperatures;
collecting results; and
interpolating in between and extrapolating around said collected results to produce a model of behavior of said battery; and
matching said behavior to requirements of said task.

The method may comprise:
obtaining a specification of requirements of a task requiring a battery;
comparing points of said database to said requirements; and
if said points match said specification then assigning said battery to said task.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced. In the drawings:

FIG. 1 is a RAGONE diagram showing energy density against power for various fuel technologies;

FIG. 2 is a simplified flow diagram illustrating a process of charging and discharging a battery under different conditions and using empirical results and then using interpolation to generate a model to govern a specific battery kind, according to embodiments of the present invention;

FIG. 3 is a simplified diagram indicating different methods of charging a battery that may be utilized in the present embodiments;

FIG. 4 is a graph illustrating the voltage during a constant current charging process carried out at different C-rates, that may be utilized in embodiments of the present invention;

FIG. 5 is a graph illustrating the voltage during a constant current discharging process carried out at different C-rates, that may be utilized in embodiments of the present invention;

FIG. 6 is a graph illustrating the voltage during a constant power discharging process carried out at different power levels, that may be utilized in embodiments of the present invention, for a temperature T=25°;

FIG. 7 is a simplified flow chart showing how the model may be built up during charging and discharging operations of a battery according to embodiments of the present invention;

FIG. 8 is an illustration of a battery diagram model in the Simulink Workspace;

FIG. 9 is a Battery data graph over the course of an 8.25 W discharge, as may be utilized in embodiments of the present invention;

FIG. 10 is a Battery data graph over the course of an 8.25 W charge, as may be utilized in embodiments of the present invention;

FIG. 11 is a comparative chart of Battery charge voltage at 1.5 C comparing empirical battery test results with the SIMULINK and PSIM models and with the model of the present embodiments;

FIG. 12 is a comparative chart of Battery discharge voltage at 1.5 C comparing empirical battery test results with the SIMULINK and PSIM models and with the model of the present embodiments;

FIG. 13 is a comparative chart of Battery charge at 16.6 W comparing empirical battery test results with the SIMULINK and PSIM models and with the model of the present embodiments;

FIG. 14 is a comparative chart of Battery discharge voltage at 16.6 W comparing empirical battery test results with the SIMULINK and PSIM models and with the model of the present embodiments;

FIG. 15 is a graph comparing an empirical battery test under varying load with the SIMULINK and PSIM models and with the model of the present embodiments;

FIG. 16 is a simplified diagram showing tracking error in the battery test under varying load between the model of the present embodiments and the SIMULINK and PSIM models;

FIG. 17 is a variation of the model of FIG. 8 in which the model is modified to include temperature as an additional variable, according to embodiments of the present invention; and

FIG. 18 is a graph showing discharge behavior of a battery according to the model of FIG. 17.

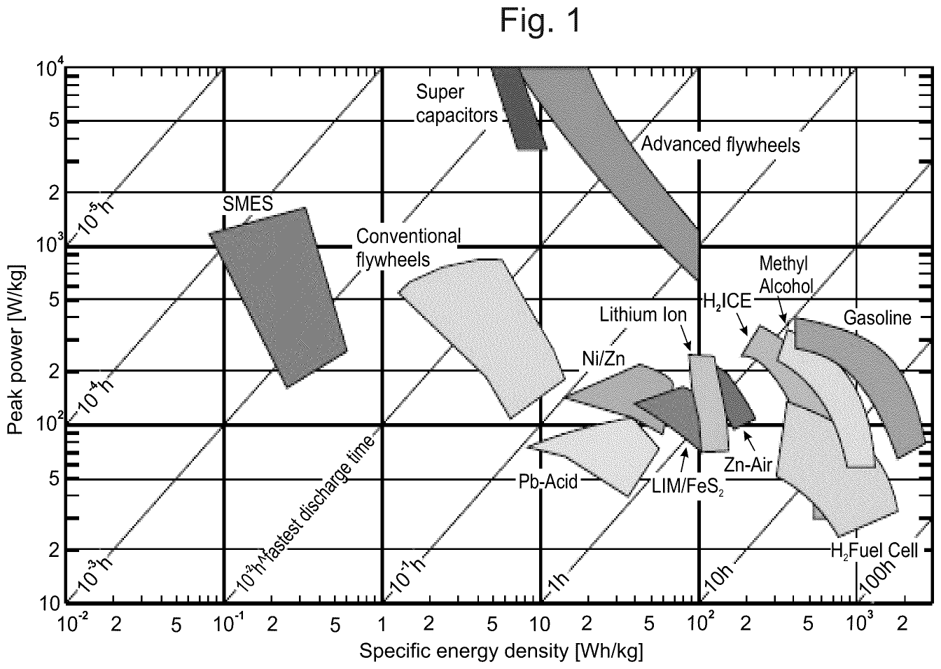

### DESCRIPTION OF SPECIFIC EMBODIMENTS OF THE INVENTION

The present invention, in some embodiments thereof, relates to a real time sizing tool for an energy storage system that uses generic modeling.

A battery model is a necessary tool for simulating battery behavior, especially for a long-period process in sizing procedures. The present embodiments may accordingly provide a generic battery model. The battery behavior is non-linear and varies according to many parameters such as temperature, current, type of load, etc. The present embodiments may receive an external sensing signal of system status and environment, and then the model characterizes the changes in the battery according to the load. The model includes battery limitations such as overcharging and provides battery parameters such as supplied and remaining energy. The model may be based on real battery test results performed under various conditions from which the data was retrieved. The measured voltage curves under different loads are inserted into the model, and the algorithm interpolates and extrapolates the data to find every necessary operating point. The results may show that a dynamic battery model according to the present embodiments is capable of predicting the battery behavior through all operating zones and under various battery conditions. The model may be capable of re-evaluation of battery behavior at many or all possible operating points. In addition, the model may supply the status of many or all battery parameters during and at the end of the simulation.

Since the algorithm of the present embodiments is generic, the model may be designed for all types of batteries by reentering data for any specific battery. A model according to the present embodiments was implemented on an LiFePO4 battery by using the Matlab-Simulink software tool, which enables real-time battery operation according to the load.

The present embodiments may thus provide a method of modeling a battery to match the battery to a task, which method comprises: selecting a battery, testing the battery for charge rate and discharge rate at different temperatures, collecting results; and interpolating in between and extrapolating around the collected results to produce a model of behavior of the battery and predict operating points, so that the battery may be sized and matched to given tasks.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

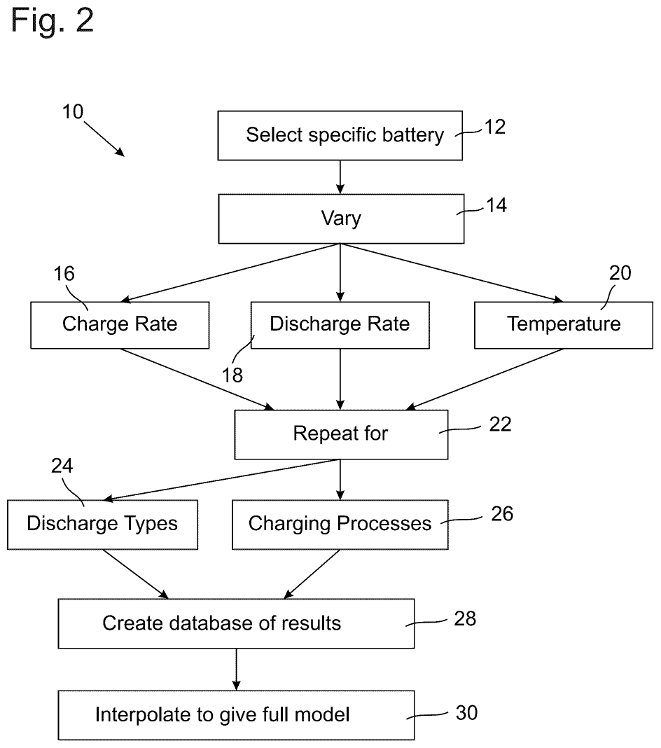

Referring now to the drawings, FIG. 2 is a simplified flow chart illustrates a generalized modeling process 10 according to the present embodiments. A battery model based on real experimental results may be provided according to the method shown in FIG. 2. The model may be implemented using the Matlab-Simulink software tool. First, a specific battery is selected to be modeled, 12. A database is created based on the specific battery selected by varying 14 charging 16 and discharging 18 rates at different temperatures 20. Battery behavior is tested by repeating 22 the above for each of different discharge types 24 such as constant current at different rates ( . . . , 0.2 C, . . . , 2 C, . . . ), constant power and ohmic load while the charging process 26 is divided into constant current at different rates at the beginning of the charging process and constant voltage near to the end. The results are placed in a database 28. Then a battery model is constructed, wherein the model may predict the behavior of the battery during the charge or discharge process by interpolating 30 the battery behavior for the missing points in the database. The model may thus have the ability to predict battery performance based on real experiments. The model may accordingly predict battery behavior in a variety of situations, thereby being able to predict accurate battery behavior and obtain actual battery behavior. A model according to the present embodiments may characterize any type of battery and is not exclusive to a specific kind of battery. The model can be set to the correct parameters of any given battery. In addition, the present embodiments may provide a means of modeling a series or hybrid battery for a desired package. Again the model may be verified by experiment on a real battery cell.

### Battery Modelling

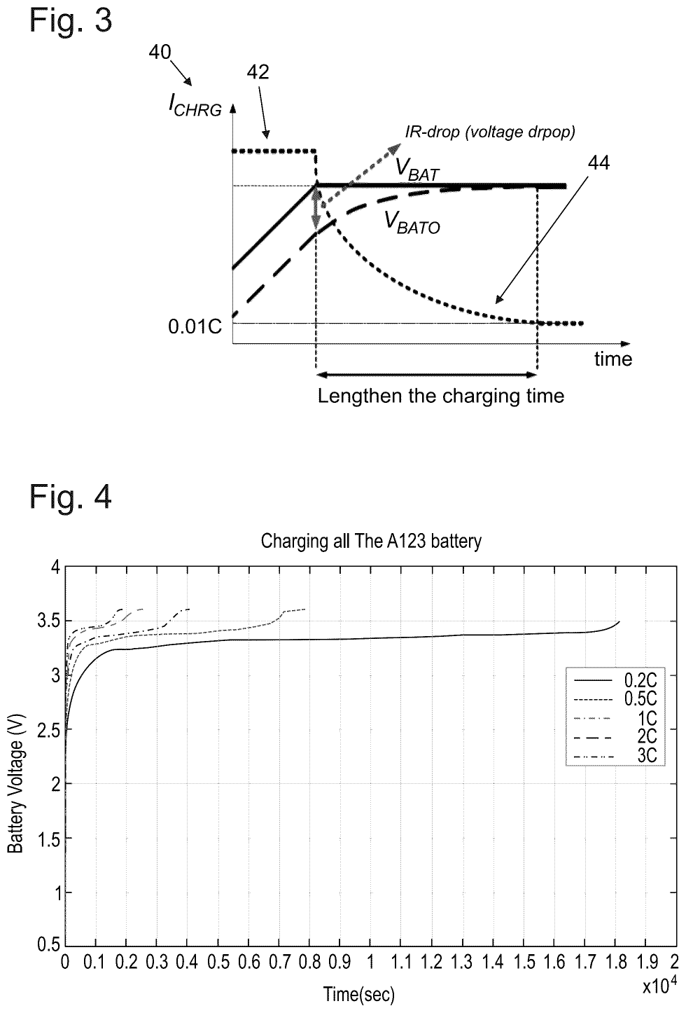

Design of new storage systems may require careful and long period validation experiments. In hybrid energy sources, a sizing procedure may be required. In such a case, the system designer may perform several iterations to fulfill a load power demand. A sizing process using real sources may take a few months and be a significant contribution to the design time and thus time to market. Accordingly, sizing may advantageously be carried out using simulation rather than a long experimental process. By using a digital model the designer may perform a rapid examination of possible lists of solutions on the sizing procedure. A first stage comprises creating a trustworthy model of each simulated source. Nonetheless, a theoretical model is insufficient to imitate actual behavior of any source and therefore, may lead to crucial failure of the designed system. A more advanced approach recruits the power of digital simulation together with substantial device behavior by creating a realistic and more accurate digital model of the specific source. The new model is based on battery testing in diverse situations. The battery is charge and discharged to various currents as presented in (5)

$${I}_{b a t t} = \pm {\sum }_{n = 0}^{4} ( 0.2 + 0.5 n ) C \qquad ( 5 )$$

where I_{batt.} is the battery current, (+) represent the charge process, (−) represent the discharge process and C is the battery C-rate. The purpose of battery testing at different current levels is to inspect the specific behavior of the battery under a variety of current levels on charge and discharge mode, and thus model the battery according to its behavior under various scenarios. The battery parameters considered in the model are battery low voltage limit, Battery high voltage limit, Battery charge current limit, Battery discharge current limit and battery efficiency. The attainment of a battery model with performance as close as possible to an actual battery may require several additional tests to be performed on charge and discharge states. Referring now to FIG. 3, the Li-ion battery charging process 40 comprises two significant stages, constant current (CC) 42 and constant voltage (CV) 44, the most common method for charging a battery.

When starting to charge a battery, the first phase is constant current, then when reaching a specific voltage level the second phase begins where the battery charger voltage is constant without any limitation on the charging current. Once the battery reaches near its maximum charging voltage, the current starts to drop from its limit until almost zero and then the charging is complete. Charge tests are conducted on a lithium-iron phosphate battery (LiFePo4) [See Table 1 below] at several C-rates as described hereinabove with respect to FIG. 2. The discharge tests are carried on the LiFePo4 battery at some C-rate as shown in FIG. 4. illustrates the results of charge experiments, it was shown that as the C-rate rise the charging time become shorter while the accumulated energy decreases and the battery SoC does not reach its full capacity.

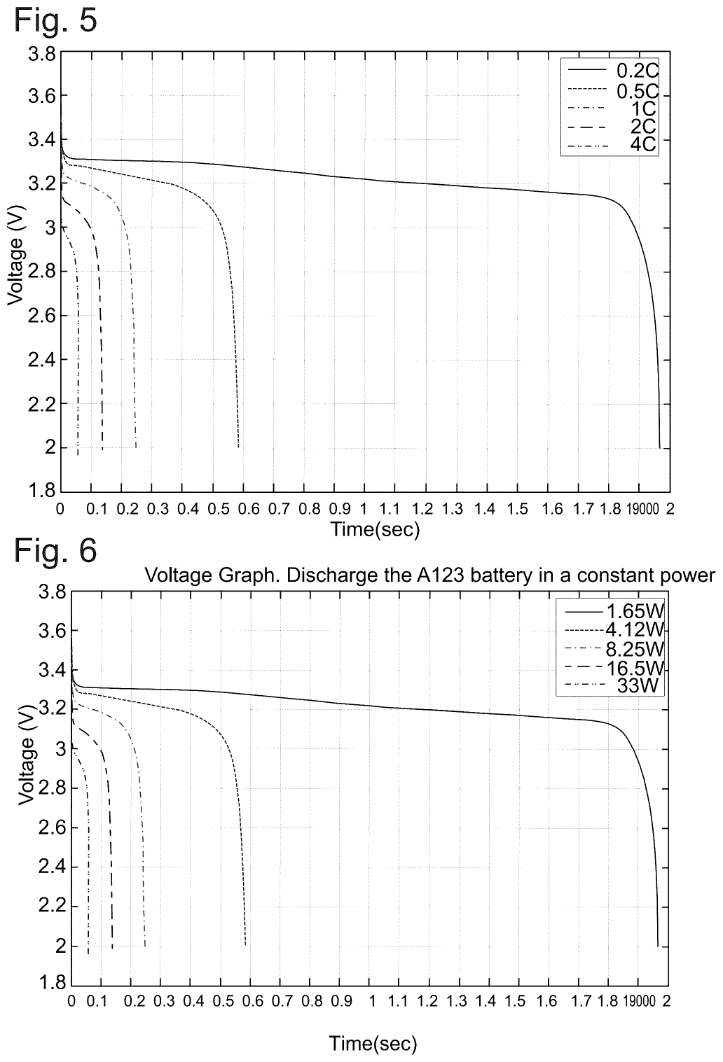

The discharge tests may also be conducted on an LiFePo4 battery, Table 1; and the possible discharging procedures are constant power and constant current. The constant current discharge process is similar to the charging process. As the C-rate rises, the battery internal losses rise while the discharge time decreases as presented in FIG. 5, which is a graph showing constant current discharging results.

Referring now to FIG. 6, another discharge procedure is constant power. Since most loads consume constant power and not constant current, this type is more likely to be used in a real load profile. The battery voltage decreases as the SoC is used up and the battery current rises to keep the power balanced. Consequently, the internal losses are increased dramatically in constant power mode and therefore, the available energy is reduced and vice versa as shown in FIG. 6, which shows constant power discharging for a temperature of T=25°.

### Real Time Modeling

As discussed hereinabove, various options are available to establish an accurate and sustainable battery model. When dealing with actual devices the battery parameters may vary within allowed boundaries. Models that are based on electrochemical equations or equivalent electrical circuits are inherently inaccurate for any production series. Thus, a lookup table based on average experimental results is more effective in forecasting battery parameters and behavior.

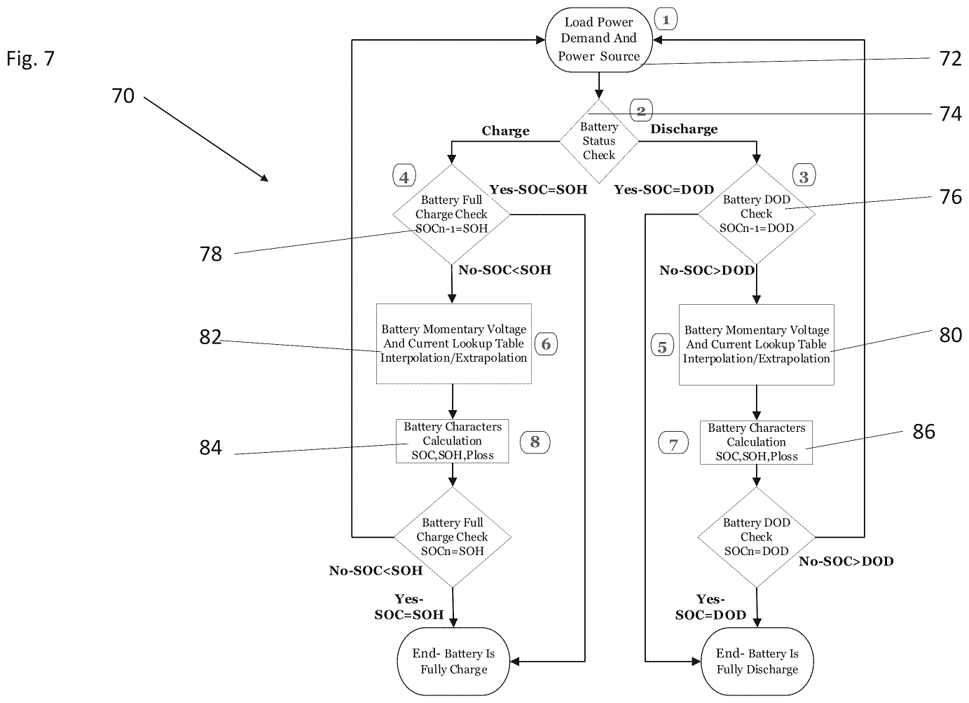

Reference is now made to FIG. 7, which illustrates a high-level battery model algorithm 70 according to embodiments of the present invention. In block 72 the model receives the load power demand and in case of external sources the power produced by the source. The status of the battery is checked 74 to determine the operation mode, that is whether the battery is being charged or discharged. Checks are made as appropriate 76 and 78. By using a power balancing equation in 80, it is possible to determine the battery status for charging or discharging. Block 74 characterizes the operation mode, whether it is charge or discharge. In case of the charge path the model verifies that the status of the battery is not beyond the SoC boundaries—78. If the battery is fully loaded the process ends. Else the linear interpolation/extrapolation begins in block 82. The charging process ends where the algorithm calculates the updates to the battery parameters in block 84 and starts the next cycle. The second option is the discharge path; the model verifies that the status of battery is not beyond the DoD boundaries in block 76. If the battery is fully discharged the process ends. Otherwise, the linear interpolation/extrapolation begins in block 80. The discharging process ends where the algorithm calculates the updates to the battery parameters in block 86 and starts the next cycle.

$${P}_{b a t t} ( n ) = {P}_{l o a d} ( n ) - {P}_{g e n} ( n ) \qquad ( 5 a )$$

In block 72 the model receives two power signals, the instantaneous required load power and the current generated power. The subtraction of both signals in 80 may set the model operating mode (charge/discharge). Then, the model may take the absolute power value and divide it by the battery current internal voltage value (V_{batt.}(n)) to verify that the model operates within the allowed battery current. The simulation manager can modify the SoC and DoD to a specific value, otherwise the model inherits this value from the previous stage (n-1). Another option is to add an ambient temperature, which the simulation manager may set as a varying temperature profile or as a constant. In block 74 the model may translate power demand to instructions for charging or discharging. The model may inspect the instantaneous current by sensing the battery internal voltage. Before starting a charge or discharge procedure the model may examines the following conditions (6a, 6b) in blocks 76 and 78.

$$SoC ( n - 1 ) < {Q}_{nom .} \qquad ( 6 a )$$

$${Q}_{min} < DoD ( n - 1 ) \qquad ( 6 b )$$

The calculated battery current (I_{batt.}(n)) and internal voltage (E_{batt.}(n)) are then processed in blocks 80 and 82 for discharging and charging respectively. The model may reveal the following parameters: instantaneous terminal voltage, battery power, energy, capacity, wasted power and energy, the remaining energy and an updated capacity.

A closer look inside blocks 80 and 82 may start with the amount of power that the model is fed. For a negative solution to the power balancing equation in block 80 the load demand is lower than the generation power, so that the battery receives power, meaning that the battery is in charging mode and vice-versa. The model is capable of supporting simulation by pack or by basic cell. In battery pack operation, the model divides the given amount of power by the number of serial and parallel cells within the battery. After the distribution of the battery power, the required power from each cell is obtained from (7).

$${P}_{cell} ( n ) = \frac{{P}_{b att .} ( n )}{n p C} \qquad ( 7 )$$

where npC is the number of paralleled cells.

From the discrete cell power the cell current is obtained in (8). If the cell power is negative (P_{cell}<0), the battery charges. When the battery charges, the battery power is multiplied by −1 to make it positive again. To obtain a controlled current source, the battery power is divided by the battery voltage.

$${I}_{cell} ( n ) = \pm 1 \cdot \frac{{P}_{cell} ( n )}{{V}_{cell} ( n )} \qquad ( 8 )$$

The next step in the process is to verify that the battery current does not exceed the maximum allowed current. In case of over current, the model imitates a battery management system (BMS) and limits the battery current as presented in (9).

$${I}_{batt} = \{ \begin{matrix}{I}_{load} , & {I}_{load} < {I}_{max , charge} \\ {I}_{max , charge} , & {I}_{load} > {I}_{max , charge}\end{matrix} \qquad ( 9 )$$

The internal voltage and battery current are now processed and data is supplied on momentary battery capacity (Ah), battery supply energy (Wh), energy lost (Wh) and energy remaining (Wh). The forward Euler method is based on a truncated Taylor series expansion. The forward Euler method is a first-order method, which means that the error per step (local error) is proportional to the square of the step size, and the error at a given time (global error) is proportional to the step size. The momentary battery capacity is estimated by the discrete Forward Euler method as presented in (10). The battery current is accumulated and added/subtracted from the present capacity in charge/discharge modes respectively.

$${Q}_{m o m} ( n ) = {Q}_{m o m} ( n - 1 ) \pm k \cdot [ t ( n ) - t ( n - 1 ) ] \cdot {I}_{b att .} ( n - 1 ) \qquad ( 10 )$$

The battery supplied/sourced (momentary) energy is also estimated by the forward Euler method. The battery internal voltage may be multiplied by the battery current resulting in the battery power accumulated to the battery energy as presented in (11).

$$( 11 )$$

$${E}_{mom .} ( n ) = {E}_{mom .} ( n - 1 ) \pm k \cdot [ t ( n ) - t ( n - 1 ) ] \cdot [ {V}_{b att .} ( n - 1 ) \cdot {I}_{b att .} ( n - 1 ) ]$$

The battery lost energy is likewise obtained using the forward Euler method. The battery current is squared and multiplied by the interpolated battery internal resistance resulting in battery energy loss as presented in (12).

$${E}_{l oss .} ( n ) = {E}_{loss .} ( n - 1 ) + k \cdot [ t ( n ) - t ( n - 1 ) ] \cdot [ {( {I}_{b att .} ( n - 1 ) )}^{2} \cdot {r}_{b att .} ] \qquad ( 12 )$$

Accordingly, the remaining battery energy or stored energy is obtained.

$${E}_{b att .} ( n ) = {E}_{i n i t i a l} \pm {E}_{mom .} ( n ) - {E}_{loss .} ( n ) \qquad ( 13 )$$

The battery SoC/DoD is calculated based on a 3-dimensional database of power, current and temperature. Since the battery data is discrete the missing operating point may be approximated by interpolation and extrapolations using a linear-point slope algorithm. A piecewise-continuous function approximation is

$$Y = F ( X ) \qquad ( 14 )$$

which may use piecewise-linear functions in the form of

$$Y = {A}_{i} ( X - {X}_{i} ) + {Y}_{i} ( {X}_{i} \leq X \leq {X}_{i + 1} ) \qquad ( 15 a )$$

$${A}_{i} = \frac{{Y}_{i + 1} - {Y}_{i}}{{X}_{i + 1} - {X}_{i}} \qquad ( 15 b )$$

Methods for finding suitable breakpoint abscissas Xᵢ and slopes Aᵢ for good approximation of a given function F(X) range all the way from seaman's-eye techniques to dynamic programming. In general, a polygonal approximation may be formed by secants crossing and re-crossing in a given curve. This method is sufficient for real-time prediction of any battery operating point between or near to the database inspected curves. The database may contain rows, columns and pages of measured values on battery power ratings for charge/discharge, current, temperature and terminal voltage. The model receives the mentioned parameters and produces a battery terminal voltage using the linear-point slope algorithm (V_{terminal.}∈{I_{batt.}, T, P_{batt.}}). The approximation procedure output is the battery terminal voltage. With use of approximation of the internal resistance (r_{batt.}) the internal battery resistance may be obtained. The battery internal voltage (V_{batt.}) is the keystone for revealing the above parameters and therefore the heart of this model. A battery internal resistance approximation may also be based on a linear-point slope algorithm. The database contains rows, columns and pages of measured values on impedance, current, temperature and calculated SoC. The approximation procedure may collect data on three mentioned parameters and may supply a present value for battery internal resistance (r_{batt.}∈{I_{batt.}, T, SoC}). The battery SoC calculation may be made using the discrete Forward Euler method, for the momentary capacity (10) and the initial capacity summation. In this method the actual capacity value is set as the battery SoC. Another option is to present the SoC as a percentage as shown in (16)

$$SoC = {Q}_{b a t t} ( n ) = {Q}_{i nitial} \pm {Q}_{m o m} ( n ) \qquad ( 16 a )$$

$$SoC ( \% ) = \frac{{Q}_{i n i tial} \pm {Q}_{m o m} ( n )}{{Q}_{nominal}} \qquad ( 16 b )$$

### Simulations and Experimental Results:

A model according to the present embodiments may be applicable to a sizing simulation system. An algorithm according to the present embodiments may allow a real time continuous operation while updating all battery parameters. A generic model according to the present embodiments was implemented for the case of an Li—FePO4 battery, whose parameters are presented in table 1. The ANR26650M1-B battery was tested under different power and current levels for charging and discharging at different temperatures. The experimental results were assembled into collected database as a basis for predicting exact battery terminal voltage and current.

TABLE 1
ANR26650M1-B Battery parameters

| | | |
|---|---|---|
| Nominal voltage | 3.3 | [V] |
| Max charging voltage | 3.6 | [V] |
| Cut off voltage | 2 | [V] |
| Nominal capacity | 2.5 | [Ah] |
| Internal resistance | 6 | [mΩ] |
| Max discharging current | 50 | [A] |
| Max charging current | 10 | [A] |

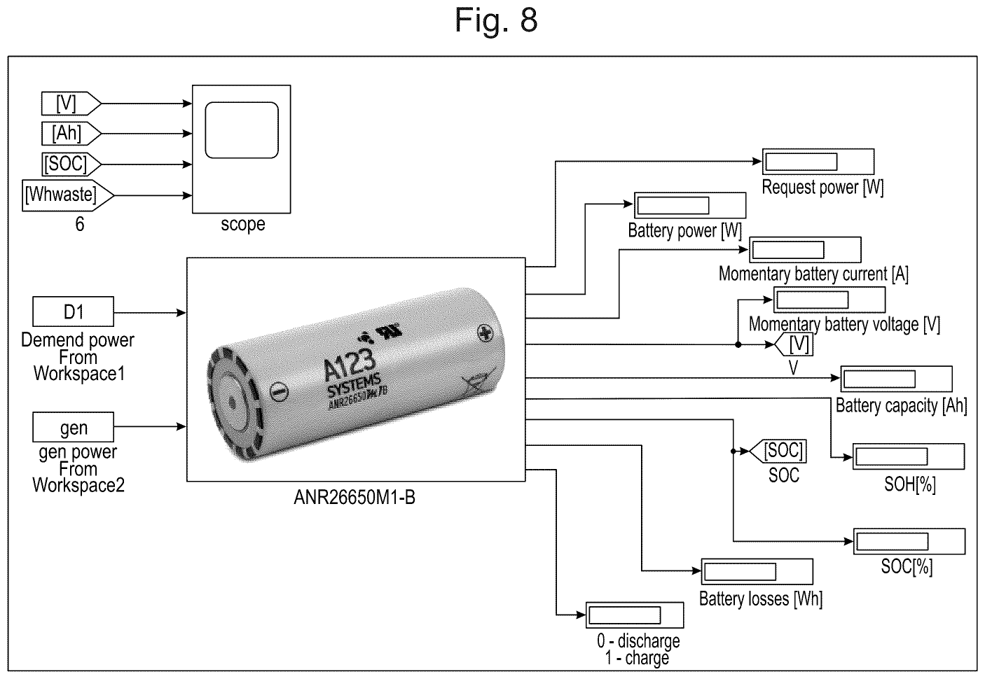

The battery model was designed using a Matlab-Simulink simulation tool as shown in FIG. 8. The model receives the load power demand and the generator supply power and by the use of equations (10)-(16) the model produces and provides the following parameters: the requested battery power, the produced battery power, the battery power, the battery terminal voltage, the battery internal voltage, battery capacity, the battery instantaneous power, battery SoC, Battery SoH and the battery power dissipation, all as presented in FIG. 8. All parameters are presented in the operator workspace and available for use for other simulation tools (e.g. sizing). The data points used in the model may be obtained by measurements taken on the specific battery during testing, that is specifically testing the battery for charge rate and discharge rate at different temperatures. The results are collected, and a process of interpolating in between and extrapolating around the collected results is used to produce a model of behavior of the battery.

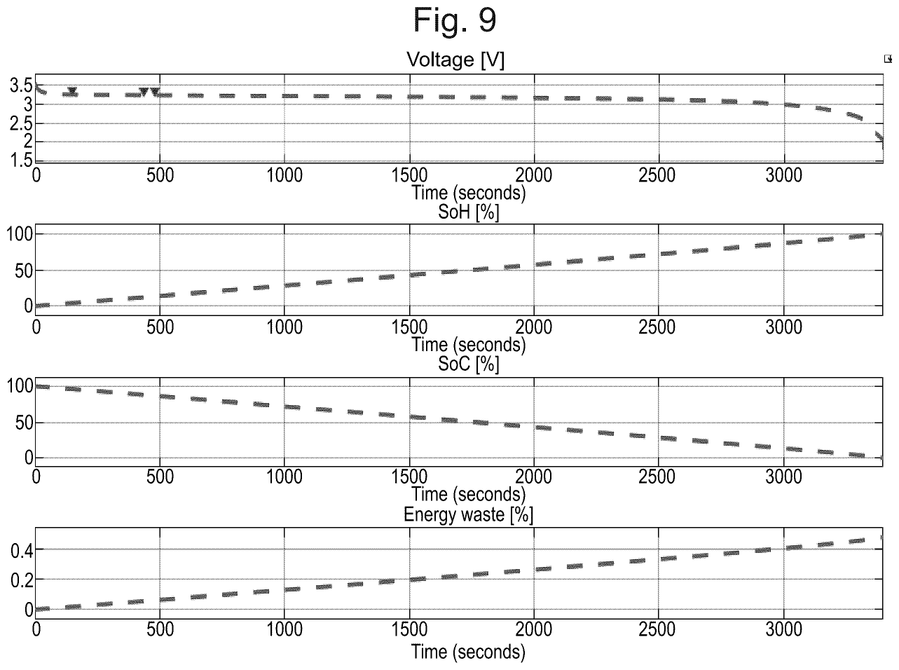

Referring now to FIG. 9, to validate the generic proposed model a discharge test was performed on the ANR26650M1-B battery using an 8.25 W discharge rate where the battery initial power was P=8.25 W. The final discharge process ends when the battery terminal voltage falls to 2V. The 2V voltage is actually one of the preconditions (DoD) for stopping the discharge process. The simulation results in FIG. 9 show that the battery provides most of the nominal stored energy at 7.701 Wh and has a run-off when the battery reaches a certain voltage, while leaving an additional un-used amount of energy of 0.5485 Wh. In addition, the battery supplies the required power and until discontinued, the running time is T=3360.65 [s] and the normalized wasted energy measured is

$$\frac{{E}_{w a s t e}}{{E}_{b a t t}} = \frac{0.0402}{8.25} \cdot 100 \% = 0.487 \% .$$

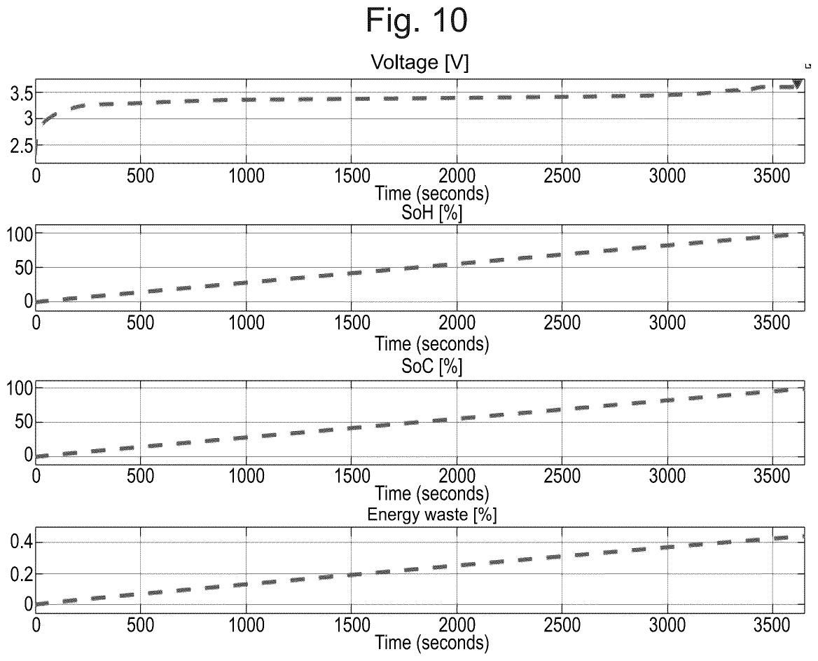

To complete the model validation a charge test was performed on the battery under the same condition of 8.25 W, the battery power was P=8.25 W. The final battery energy is 8.25 Wh which is one of the preconditions for ending the charging process as presented in FIG. 10. After reaching the final energy, the battery recharges to its required power and the running time until the break is T=3600 [s].

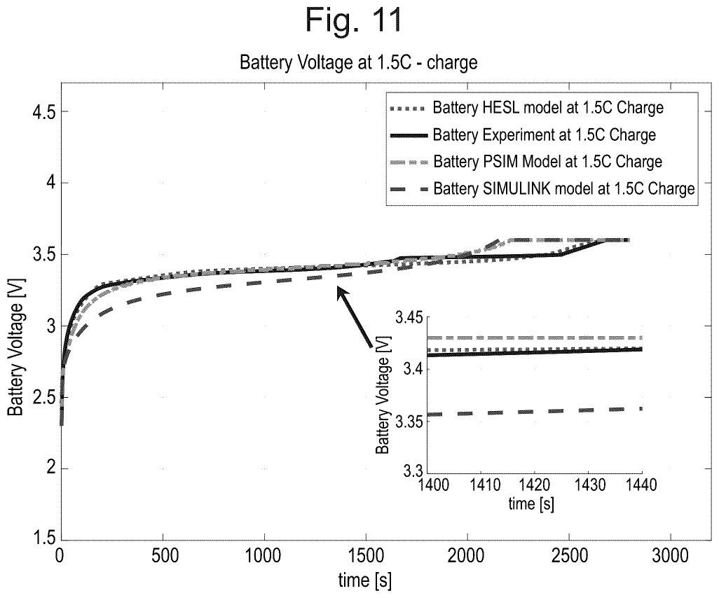

Since the model utilizes the discrete Forward Euler method to interpolate the battery operating point the battery validation process may be set to 1.5 C, so that testing is performed at a point not appearing in the database, so that the Euler function is brought into action and the battery voltage is accordingly evaluated. An actual charging test at 1.5 C was carried out and found to equal the simulation results. The model may thus present a tight prediction that tracks the actual testing results, or in other words the model may follow the actual results with small perturbations. As shown in FIG. 11, which is a comparison showing battery charge voltage at 1.5 C using battery test and against model, the model may be shown to predict the actual battery behavior with high certainty.

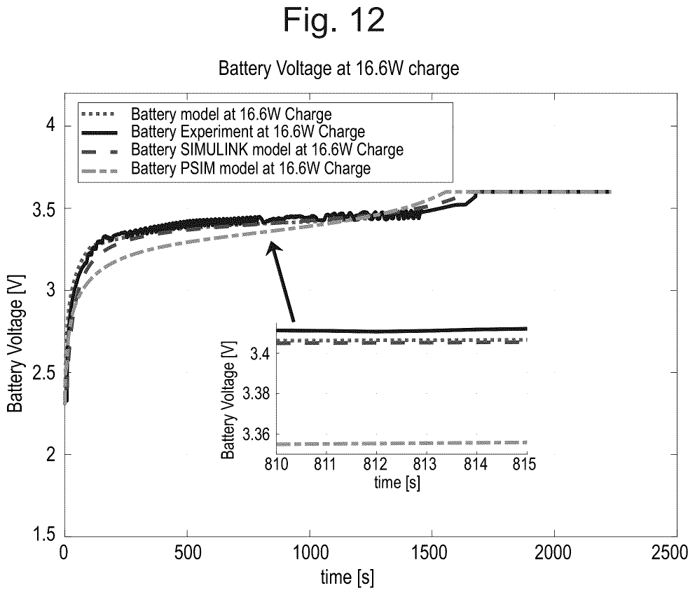

The actual discharge performance is similar to the discharge simulation results. The model was tested under the same C-rate (1.5 C) as with the charge test. The model again presents close tracking estimation capabilities over the discharge curve as presented in FIG. 12.

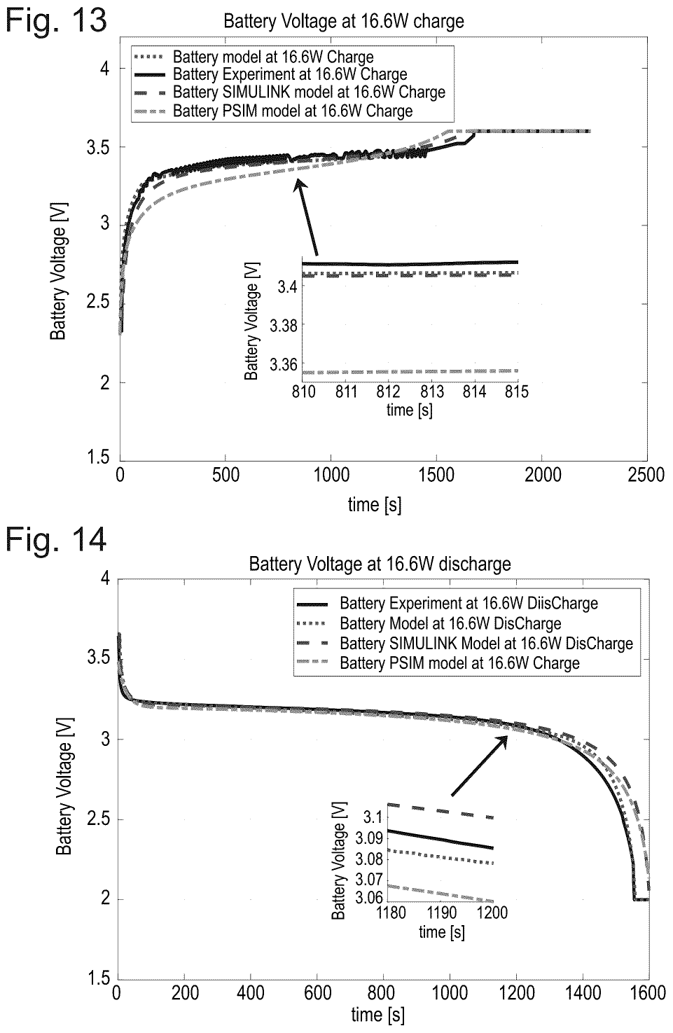

Many loads require specified power, thus, if the source voltage is not constant the supplied current may change accordingly. In sizing procedures, the battery model may receive a power demand, so that when the battery voltage starts to drop the battery current rises to compensate and keep the power constant. To verify the model behavior under such requirements, the model was tested under constant power demand and equated to experimental results for charging at constant power of 16.6 W and discharging for 16.6 W as presented in FIG. 13 and FIG. 14 respectively. The results show that the model predicts the battery behavior very accurately and supplies a reliable tool for simulating the battery in the sizing algorithm. FIG. 13 shows the battery charge voltage at 16.6 W for battery test against model, and FIG. 14 shows the battery discharge voltage at 16.6 W for battery test against model.

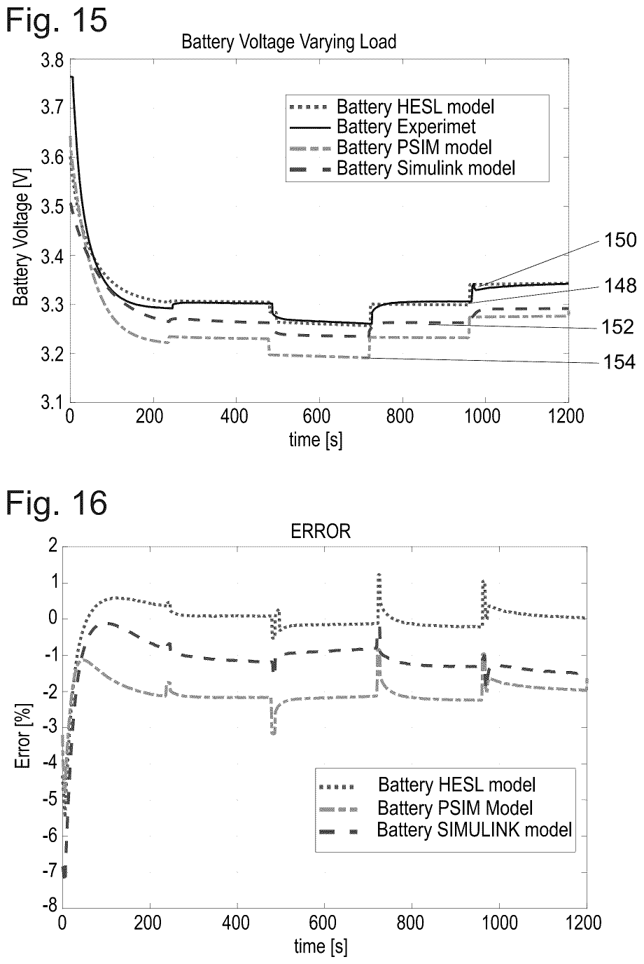

Reference is now made to FIG. 15, which illustrates a comparison between the present embodiments and the SIMULINK and PSIM models. To verify the new model performance a battery cell was tested under continuous varying power load with similar behaviour of load profile in sizing simulation. The load is able to carry out three different power discharge processes from a fully charged battery. Then the battery is charged in two steps at various power levels. The experimental results—solid line 148, were then equated with the model of the present embodiments—dotted line 150, the SIMULINK model—long dashed line 152 and the PSIM model—short dashed line 154. The evaluation of the simulation results shows that the model of the present embodiment may outperform the other models as presented in FIG. 15.

Reference is now made to FIG. 16, which shows the error in tracking the experimental results by each of the models. Tracking using the model of the present embodiments presents an error indicated by dotted line 160, the SIMULINK model—long dashed line 162 and the PSIM model—short dashed line 154. The figure shows that tracking according to the present embodiments may present a significant improvement of the present embodiments over the other models.

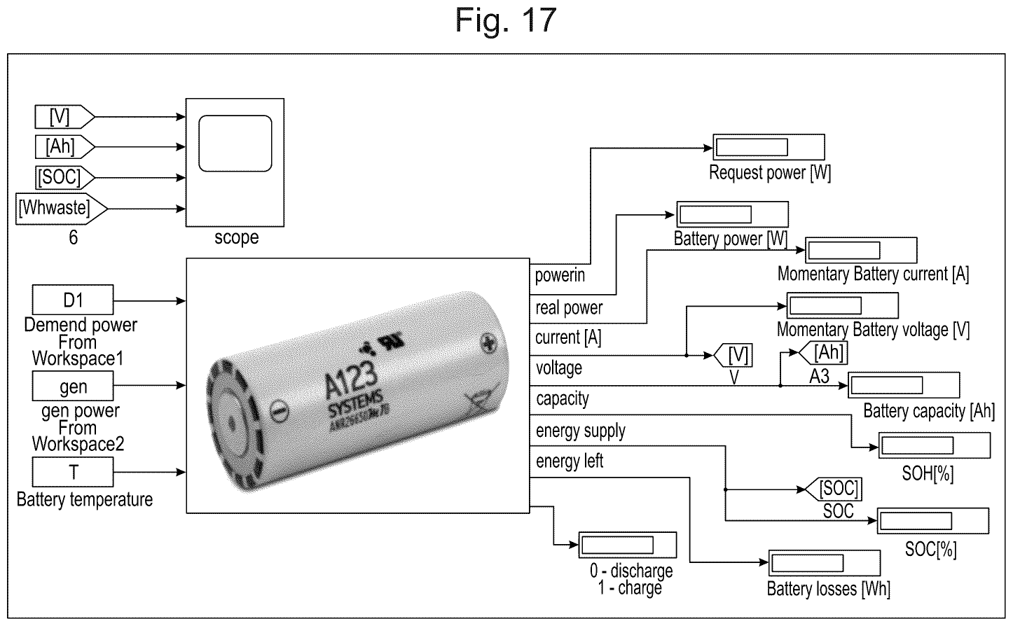

Reference is now made to FIG. 17, which illustrates a variation of the battery model using a Matlab-Simulink simulation tool as shown in FIG. 8. In the variation, battery temperature is used as an additional model input. The model receives the load power demand and the generator supply power and by the use of equations (10)-(16) the model produces and provides the following parameters: the requested battery power, the produced battery power, the battery power, the battery terminal voltage, the battery internal voltage, battery capacity, the battery instantaneous power, battery SoC, Battery SoH and the battery power dissipation. All parameters are presented in the operator workspace and available for use for other simulation tools (e.g. sizing).

As explained above, the data points used in the model may be obtained by measurements taken on the specific battery during testing, that is specifically testing the battery for charge rate and discharge rate at different temperatures. The results are collected, and a process of interpolating in between and extrapolating around the collected results is used to produce a model of behavior of the battery.

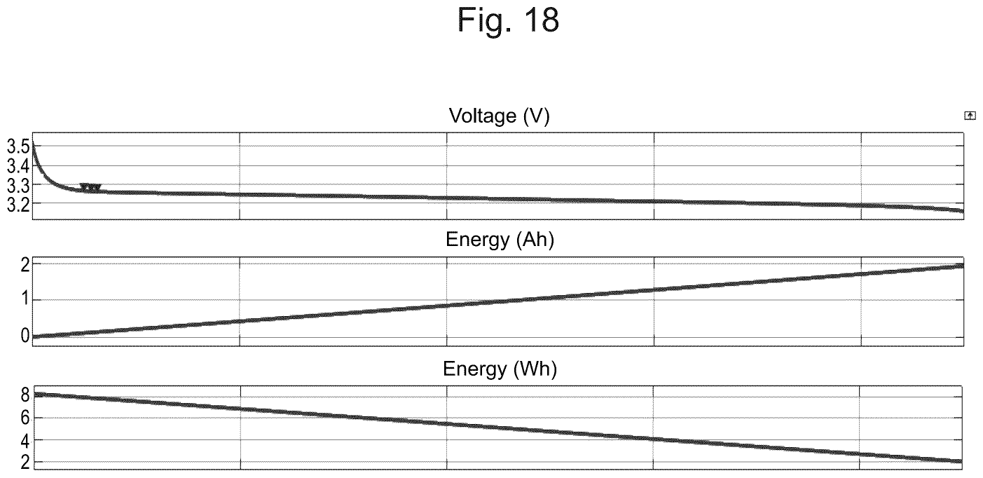

Reference is now made to FIG. 18, which is a simplified diagram illustrating discharge of the battery using the model of FIG. 17, and showing voltage, current and power outputs.

Accordingly, a real-time battery model may be provided according to the present embodiments. The model may be based a basic database created by testing of actual battery operation. The model may only require a load power demand and by analysis, interpolations and extrapolations, the model predicts the battery behavior and anticipates the battery terminal voltage, current, power, SoC. SoH and internal losses at any optional operating point without additional information.

Since the model requires only power demand, it may be suitable for sizing procedures and may operate in continuous cycles of charging and discharging. The experimental results may present high-accuracy prediction capabilities of the model at operating points interpolated by the algorithm in the charging and discharging process. A generic model according to the present embodiments may be assembled into a large-scale power system simulation and may anticipate storage system behavior. Since the model is generic, it may allow modification of battery technology and capacity by short testing.

In this description and the appended claims, the terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment and the present description is to be construed as if such embodiments are explicitly set forth herein. Conversely, various features of the invention, which are, for brevity, described in the context of a single embodiment, may also be provided separately or in any suitable subcombination or may be suitable as a modification for any other described embodiment of the invention and the present description is to be construed as if such separate embodiments, subcombinations and modified embodiments are explicitly set forth herein. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

TABLE 2
A: Battery data sheet type LiFePo_4 lithium-iron phosphate:

| APPLICATIONS | ANR26650 [symbol] 1-B TECHNICAL DATA | | |
|---|---|---|---|
| COMMERCIAL SOLUTIONS | Cell Dimensions | Ø26 × 65 | mm |
| Advanced lead acid replacement | | | |
| batteries for: | | | |
| +Datacenter UPS | Cell Weight | 76 | g |
| +Telecom backup | Cell Capacity (nominal/minimum) | 2.5/2.4 | Ah |
| | (0.5 C Rate) | | |
| +IT backup | Voltage (nominal) | 3.3 | V |
| +Autonomously guided vehicles | Internal Impedance | 6 | mΩ |
| (AGVs) | (1 kHz AC typical) | | |
| +Industrial robotics and | Power* | 2600 | W/kg |
| material handling equipment | | | |
| +Medical devices | Recommended Standard Charge Method | 2.5 A to 3.6 V CCCV, | |
| | | 60 min | |
| | Recommended Fast Charge Method to | 10 A to 3.6 V CC, | |
| | 80% SOC | 12 min | |
| GOVERNMENT SOLUTIONS | Maximum Continuous Discharge | 50 | A |
| +Military vehicles | Maximum Pulse Discharge (10 seconds) | 120 | A |
| +Military power grids | Cycle Life at 20A Discharge, 100% DOD | >1,000 | cycles |
| +Soldier power | Operating Temperature | −30° C. to 55° C. | |
| +Directed energy | Storage Temperature | −40° C. to 60° C. | |
| GRID SOLUTIONS | * ~200 W as measured by A123 modified HPPC | | |
| | Metod @23° C., 50% SOC, 10 second discharge | | |
| Versatile, flexible and proven | | | |
| storage solutions for the grid: | | | |
| +Frequency regulation | | | |
| +Renewables integration | | | |
| +Reserve capacity | | | |
| +Transmission and distribution | | | |
| TRANSPORTATION SOLUTIONS | | | |
| Hybrid, plug-in hybrid and electric | | | |
| vehicle battery systems for: | | | |
| +Commercial vehicles | | | |
| +Off-highway vehicles | | | |
| +Passenger vehicles | | | |

1. A method of modeling a battery to match the battery to a task, the method comprising:
selecting a battery;
testing the battery for charge rate and discharge rate at different temperatures;
collecting results; and
interpolating in between and extrapolating around said collected results to produce a model of behavior of said battery.

2. The method of claim 1, comprising repeating said discharge rate tests for different types of discharge.

3. The method of claim 2, wherein said discharge types comprise one member of the group consisting of: a constant current discharge at a given discharge rate, a constant voltage discharge, discharge with a fixed Ohmic load, and a constant power discharge.

4. The method of claim 1, comprising repeating said testing the battery for charge rate, for different charging processes.

5. The method of claim 4, wherein said charging processes comprise a constant current charging period followed by a constant voltage charging period.

6. The method of claim 1, wherein said collecting results comprises tabulating said results in a database.

7. The method of claim 6, wherein said database is a three-dimensional database of power, temperature and current.

8. The method of claim 1, wherein said interpolation and extrapolation comprises using a linear point slope algorithm.

9. The method of claim 1, wherein said interpolation and extrapolation comprises finding a polygonal approximation formed by secants crossing and re-crossing in a given curve.

10. The method of claim 6, wherein said interpolation and approximation provides a prediction of a battery operating point between points in said database or outside of but in proximity to said points in said database.

11. A method of sizing a battery to match the battery to a task, the method comprising:
selecting a battery;
testing the battery for charge rate and discharge rate at different temperatures;
collecting results; and
interpolating in between and extrapolating around said collected results to produce a model of behavior of said battery; and
matching said behavior to requirements of said task.

12. The method of claim 11, comprising repeating said discharge rate tests for different types of discharge.

13. The method of claim 12, wherein said discharge types comprise one member of the group consisting of: a constant current discharge at a given discharge rate, a constant voltage discharge, discharge with a fixed Ohmic load, and a constant power discharge.

14. The method of claim 11, comprising repeating said testing the battery for charge rate, for different charging processes.

15. The method of claim 14, wherein said charging processes comprise a constant current charging period followed by a constant voltage charging period.

16. The method of claim 11, wherein said collecting results comprises tabulating said results in a database.

17. The method of claim 16, wherein said database is a three-dimensional database of power, temperature and current.

18. The method of claim 11, wherein said interpolation and extrapolation comprises using a linear point slope algorithm.

19. The method of claim 11, wherein said interpolation and extrapolation comprises finding a polygonal approximation formed by secants crossing and re-crossing in a given curve.

20. The method of claim 16, wherein said interpolation and approximation provides a prediction of a battery operating point between points in said database or outside of but in proximity to said points in said database.

21. The method of claim 1, comprising:
obtaining a specification of requirements of a task requiring a battery;
comparing points of said database to said requirements; and
if said points match said specification then assigning said battery to said task.
